(19) United States
(12) Patent Application Publication
(10) Pub. No.: US 2014/0049259 A1
(43) Pub. Date: Feb. 20, 2014

(54) RESONANT MAGNETIC RING ANTENNA

(71) Applicant: Lockheed Martin Corporation, Bethesda, MD (US)

(72) Inventors: Nelson Poon, Palmdale, CA (US); Clara Baleine, Orlando, FL (US); Christina Drake, Oviedo, FL (US)

(73) Assignee: Lockheed Martin Corporation, Bethesda, MD (US)

(21) Appl. No.: 13/967,583

(22) Filed: Aug. 15, 2013

Related U.S. Application Data
(60) Provisional application No. 61/684,625, filed on Aug. 17, 2012.

(51) Int. Cl. G01R 33/34

(52) U.S. Cl. CPC G01R 33/34092
USPC 324/322

(57) ABSTRACT

A resonant magnetic ring antenna which includes a dielectric substrate having opposing first and second sides, a first and second ring elements disposed upon the opposing first and second sides of the substrate in a corresponding location, the first and second ring elements each comprising a trace having a spiral configuration with an outer radius, an inner radius, a spacing, and a number of turns, the resonant magnetic ring antenna being configured to concentrate radio frequency (RF) electromagnetic fields over a controlled volume at a specified distance from an imaging device in which it is incorporated.

### CROSS REFERENCE TO RELATED APPLICATION(S)

This application claims priority to provisional application Ser. No. 61/684,625, filed Aug. 17, 2012, and entitled “RESONANT MAGNETIC RING ANTENNA” the contents of which are incorporated in full by reference herein.

### FIELD

The embodiments herein generally relate to systems, apparatus and methods for magnetic resonance imaging systems, and more specifically, to systems, apparatus and methods for a resonant magnetic ring antenna operable for use with a magnetic resonance imaging system.

### BACKGROUND

Magnetic resonance (MR) tomography is an invaluable tool for the non-invasive generation of digital images of subcutaneous human and animal tissue in vivo. MR tomography typically involves a technique of obtaining images of the inside of a target or region of interest (e.g., the body of a living proband). When the target is placed inside a bore or opening of a MR imaging system tissue water within the body is subjected to magnetic fields on the order of 1.5 Tesla (T) to 3 T in human beings and up to 17 T for animals (hence the term “magnetic” in magnetic resonance imaging). The basic magnetic field of the MR imaging system, hereafter referred to as B₀ field, is as homogenus as possible and aligns the magnetic moment of precessing water protons in the direction of B₀ field. Protons precess at particular frequencies, depending on the strength of B₀ field. For water protons (the most common nuclei examined my MRI scanners) the precession angular frequency for the proton magnetic moment vector is given by:

ω=yB₀

where y is a constant referred to as the gyromagnetic ratio. The hydrogen proton in water has a y value of approximately 2.68×10⁸ rad/s/Tesla (so y/2π=42.6 MHz/Tesla). For water protons subjected to a magnetic field strength of 1.5 T, for example, the frequency of precession will be 63.86 MHz. The B₀ field is created by a basic field magnet system of the MR system. The B₀ field is overlaid during the magnetic resonance imaging with rapidly switched gradient fields for local encoding. The gradient fields are generated by gradient coils. High-frequency pulses of a defined field strength (e.g., the “B₁ field”) are beamed (e.g., radiated) with high-frequency antennas into the target under examination. The nuclear resonance of the atoms in the target under examination are excited by the high-frequency pulses, such that the high-frequency pulses are deflected by an “excitation flip angle” from the position of equilibrium in parallel to the B₀ field. The nuclear resonances process around the direction of the B₀ field. The magnetic resonance signals generated thereby are received by high-frequency receive antennas. The magnetic resonance images of the target under examination are created based on the received magnetic resonance signals.

Conventionally and in an attempt to optimize the image created, metamaterial approaches have been employed. The metamaterial approaches are used to create electrically small antennas, typically in the frequency ranges of ˜300 MHz. For ultra-low frequencies, even the smallest resonant antennas require the use of superconducting materials to achieve a resonance. Disadvantageously, conventional antenna types require a tuning or retuning upon loading. Further, conventional systems have heretofore been unable to maintain a robust 50 ohm (Ω) matching upon loading without a retuning of the antenna. Still further, certain high Q resonant antennas suffer from near field 1/R̂3 field decay drop off of the magnetic portion of the RF field. Such electrically small antenna approaches do not demonstrate desired concentration of the field.

### SUMMARY OF THE DISCLOSURE

The embodiments herein are designed to provide a low cost and efficient resonant magnetic ring antenna (MRA) operable for use with magnetic resonance (MR) imaging systems, direct magnetic imaging (DMI) systems, and the like. In all example embodiments, the disclosed systems, apparatus and methods for a MRA include a first ring element connected to a substrate at a first side, a second ring element connected to the substrate at a second side. In example embodiments, the disclosed systems, apparatus and methods for a MRA include a first ring element connected to a substrate at a first side, a second ring element connected to the substrate at a second side, and the MRA being connected to coupled to a metamaterial lens or metalens (MM Lens) structure thereby forming a MRA/MM Lens configuration. The MRA/MM Lens configuration is thereafter disposed or incorporated within a MR imaging system, such as, but not limited to, a MRI or a DMI.

The example embodiments herein relate to a MRA device that is capable of concentrating a source of radiofrequency (RF) electromagnetic fields fed in from a feedline and over a controlled volume at a specified distance from the imaging device. Further, the MRA described herein provides a robust 50Ω concentrated field. In example embodiments the MRA/MM Lens configuration enhances field decay drop off from a source and further concentrates the radiofrequency (RF) electromagnetic field, thus enhancing the sensitivity of the MRI or DMI over the region defined by a focal spot by an amount that is directly correlated with the increased field amplitude per unit electric current of the source. In some example embodiments, the MRA or the MRA/MM Lens configuration may be incorporated into an imaging device for imaging/irradiating and/or other diagnostic or treatment techniques directed at organs/tissues deep inside the body (for example, the prostate, the pancreas, etc.). Variations of the disclosed MRA may be used in MR devices and systems without requiring tuning capacitors to compensate for loading effects and 50Ω matching.

In an example embodiment, the MRA may be disposed upon or connected to an isotropic MM Lens structure. Such a configuration increases the detection depth of a magnetic resonance imaging (MRI) system inside the body. This configuration also enhances the magnetic field strength at the receiving coil, and thus increases the received signal power, thereby increasing the signal-to-noise ratio (SNR). As the MRI scan time is inversely proportional to the square of the SNR, modest improvements in SNR advantageously reduce the scan time.

In example embodiments, the MRA/MM Lens configuration may be incorporated into a traditional MRI device or system as an external component that can be plugged into the device in the same manner as other, optional receive coils.

Additional features and advantages of the embodiments herein will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description present example embodiments, and are intended to provide an overview or framework for understanding the nature and character of what is claimed. The accompanying drawings are included to provide a further understanding of the embodiments, and are incorporated into and constitute a part of this specification. The drawings illustrate various embodiments, and together with the detailed description, serve to explain the principles and operations thereof.

### BRIEF DESCRIPTION OF THE DRAWINGS

The present subject matter may take form in various components and arrangements of components, and in various steps and arrangements of steps. The appended drawings are only for purposes of illustrating example embodiments and are not to be construed as limiting the subject matter.

FIG. 1 is a perspective diagram of a resonant magnetic ring antenna (MRA) constructed in accordance with an example embodiment;

FIG. 2 is a cross-sectional side view diagram of a resonant magnetic ring antenna (MRA) constructed in accordance with an example embodiment;

FIG. 3 is an example miniaturization approach which may be used to increase the electrical size of the magnetic ring antenna as well as the radiation, bandwidth, and efficiency;

FIG. 4 is a predicted near field E field and H field at 8.5 MHz diagram for the resonant magnetic ring antenna of FIG. 1;

FIG. 5 is a predicted far field pattern for the resonant magnetic ring antenna of FIG. 1;

FIG. 6 is a predicted near field pattern for the resonant magnetic ring antenna of FIG. 1;

FIG. 7 shows predicted S₁₁ values for a 50Ω source obtained for the resonant magnetic ring antenna of FIG. 1;

FIG. 8 shows predicted voltage standing wave ratio (VSWR) values for a 50Ω source obtained for the resonant magnetic ring antenna of FIG. 1;

FIG. 9 shows a response of the resonant magnetic ring antenna of FIG. 1 plotted on a Smith Chart;

FIG. 10 shows measured S₁₁ values for a 50Ω source obtained for the resonant magnetic ring antenna of FIG. 1 in comparison to the resonant magnetic ring antenna disposed upon a metamaterial lens structure;

FIG. 11 shows comparative, measured SWR results for the MRA of FIG. 1, the MRA of FIG. 1 in conjunction with water loading and the MRA of FIG. 1 in conjunction with a metamaterial lens structure and water loading;

FIG. 12 shows comparative, measured S₂₁ results for various distances;

FIG. 13 is a schematic diagram of a metamaterial lens array and incorporated into an imaging device;

FIG. 14 is a schematic diagram of the resonant magnetic ring antenna disposed upon a metamaterial lens array and incorporated into an imaging device; and

FIG. 15 shows comparative, measured results for amplitude (dB) for the MRA of FIG. 1 and the MRA of FIG. 1 in conjunction with a metamaterial lens structure.

### DETAILED DESCRIPTION

Various example embodiments will now be described more fully with reference to the accompanying drawings in which only some example embodiments are shown. Specific structural and functional details disclosed herein are merely representative for purposes of describing example embodiments. The embodiments herein, however, may be embodied in many alternate forms and should not be construed as limited to only the example embodiments set forth herein.

Accordingly, while example embodiments of the disclosure are capable of various modifications and alternative forms, embodiments thereof are shown by way of example in the drawings and will herein be described in detail. It should be understood, however, that there is no intent to limit example embodiments to the particular forms disclosed. On the contrary, example embodiments are to cover all modifications, equivalents, and alternatives falling within the scope of the claims. Like numbers refer to like elements throughout the description of the figures.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or,” includes any and all combinations of one or more of the associated listed items.

It will be understood that when an element is referred to as being “connected,” or “coupled,” to another element, it can be directly connected or coupled to the other element or intervening elements may be present. In contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein are interpreted accordingly.

The embodiments herein are designed to provide a low cost and efficient resonant magnetic ring antenna (MRA) configured for use with magnetic resonance (MR) imaging systems. Example embodiments presented herein disclose systems, apparatus and methods for a MRA operable for use with magnetic resonance imaging devices (MRIs), direct magnetic imaging devices (DMIs), or other devices configured to perform imaging. Advantageously, the disclosed systems, apparatus and methods are capable of concentrating a source of radio frequency (RF) electromagnetic fields over a controlled volume at a specified distance from the imaging device in which it is incorporated. Further, the disclosed systems, apparatus and methods provide a MRA having a robust 50Ω (ohm) concentrated field. Still further, when used in conjunction with a metamaterial lens structure (MM Lens), the systems, apparatus and methods further concentrate the RF electromagnetic field and provide an enhanced amplitude (improved the field decay drop off below 1/R̂3) at distances not achievable by conventional systems. This, in turn, increases the sensitivity of the MR imaging system over a target region defined by a focal spot, the increase being by an amount that is directly correlated with increased field amplitude per unit electric current of the source. Still further, the systems, apparatus and methods disclosed herein provide a MRA which remains 50Ω matched upon loading without the need for tuning. Still further, the systems, apparatus and methods disclosed herein provide a MRA which remains matched upon loading without the need for tuning capacitors to compensate for loading effects. Still further, when used in conjunction with a MM Lens, the detection depth of the MR imaging system is increased inside the target body or region of detection. The disclosed configurations also enhance the magnetic field strength of a receiving coil located within the MR imaging system, and thus increase the received signal power, increasing the signal-to-noise-ratio (SNR). Advantageously, by increasing the SNR, improvements in scan time are provided as scan time is inversely proportional to the square of the SNR. Still further the systems, apparatus and methods disclosed herein are capable of providing magnetic fields on the order of 0.2 Tesla (T) to 3 T in human beings and up to 17 T for animals.

In all example embodiments, the disclosed systems, apparatus and methods for a MRA include a substrate having opposing first and second sides, a first ring element connected to the substrate at the first side, and a second ring element connected to the substrate at the second side. In other example embodiments, the MRA includes a substrate having opposing first and second sides, a first ring element connected to the substrate at the first side, and a second ring element connected to the substrate at the second side, the MRA being coupled to a MM Lens structure to form a MRA/MM Lens configuration, the MRA/MM Lens configuration being disposed or incorporated within a MR imaging system, such as, but not limited to, a magnetic resonance imaging (MRI) device.

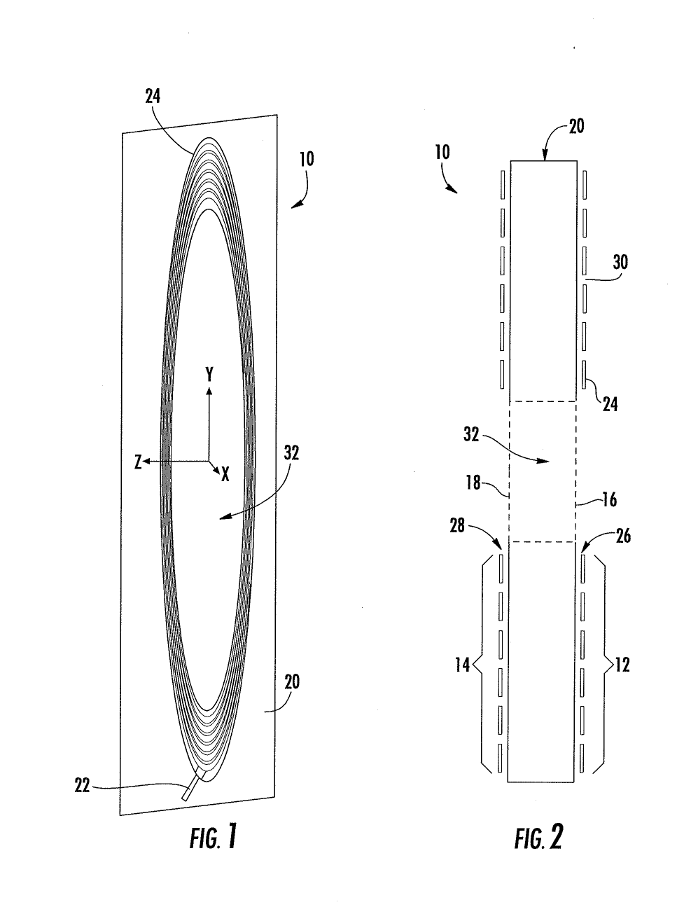

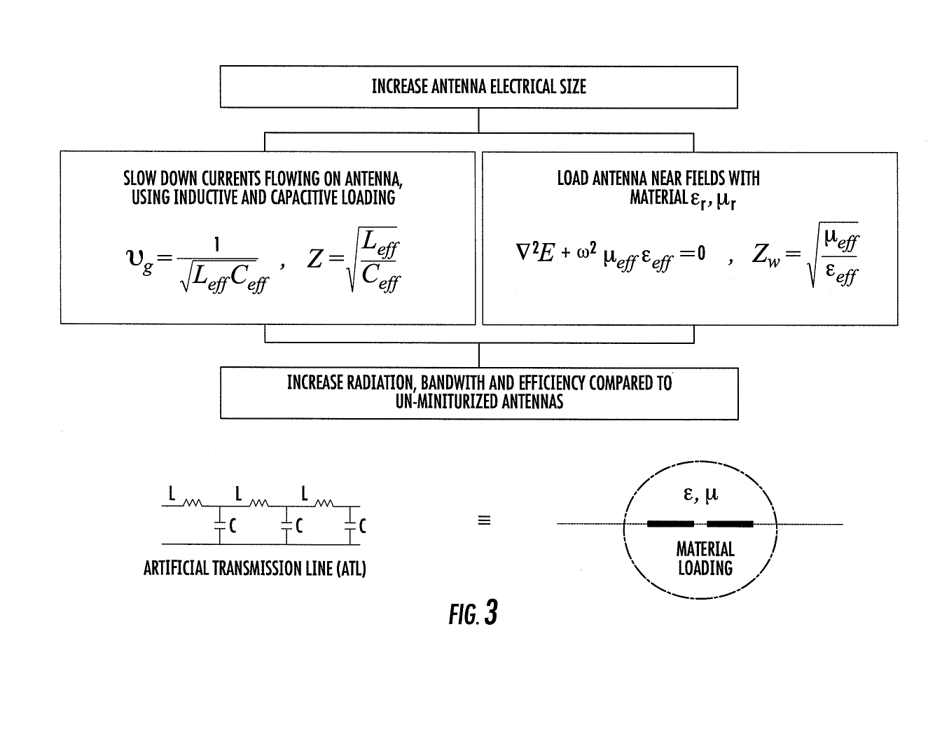

Referring now to FIGS. 1 and 2, a resonant magnetic ring antenna (MRA) is shown and constructed in accordance with an example embodiment. As shown, an MRA 10 is provided and has a generally planar, circular or ring shape. The MRA 10 includes first and second ring elements 12 and 14, connected to opposing first and second sides 16 and 18, respectively, of a substrate 20. In the example embodiments shown, the first and second ring elements 12, 14 are layered onto opposing sides of the substrate 20 in a corresponding, adjacent location. In example embodiments, the substrate 20 is a dielectric material. In other example embodiments, the substrate 20 is a high frequency circuit material. In still other example embodiments, the substrate 20 is a ceramic-filled polytetrofluroethylene (PTFE) material, such as, for example, the RO3010 substrate available from Rogers Corporation®. In example embodiments, the substrate 20 is homogeneous and exhibits strong anisotropic properties. In example embodiments, the MRA 10 is fed radio frequency (RF) electromagnetic fields from a source (not shown) and through a feedline 22, e.g., a 50-ohm (Ω) coaxial feedline.

In example embodiments, each of the first and second ring elements 12, 14 have a substantially planar, cyclic symmetry and are comprised of a material transmission-line (TL) or trace 24 extending in a circular manner to form a spiral or coil configuration and to produce specific resonances and magnetic fields to detect spectral frequencies of a target or materials of interest. In other example embodiments, the spiral configuration may have any circular shape, elliptical shape, or polygonal shape. Possible polygonal shapes include, but not limited to, a triangular, square, rectangular, pentagonal, hexagonal, heptagonal, or octagonal shape. Further, each of the first and second ring elements 12, 14 are provided with outer and inner radii 26 and 28, example radii being 5.75 inches and 4.75 inches, respectively. In still other example embodiments, each of the first and second ring elements 12, 14 are comprised of a spiral material extending for a defined number of turns. In the example embodiment shown, the number of turns is six (6) and the material is spaced apart throughout the spiral by a spacing 30 of approximately 0.06 inches. Those skilled in the art will appreciated that the number of turns, the spacing 30 and the radii 26, 28 of the first and second rings 12, 14 may vary without departing from the scope of the embodiments or claims. Further, those skilled in the art will appreciate that the material composition of the trace 24 may vary depending upon the desired effect and performance, however, in example embodiments, the material is metallic. In other example embodiments, the material is copper.

In example embodiments, the substrate 20 is provided with an aperture 32 which corresponds in size to the inner radius 26 of the first and second ring elements 12, 14. In example embodiments, the first and second ring elements 12, 14 are layered upon the substrate 20 such that the inner radii 26 of the first and second ring elements 12, 14 corresponds in location to the radius of the aperture 32.

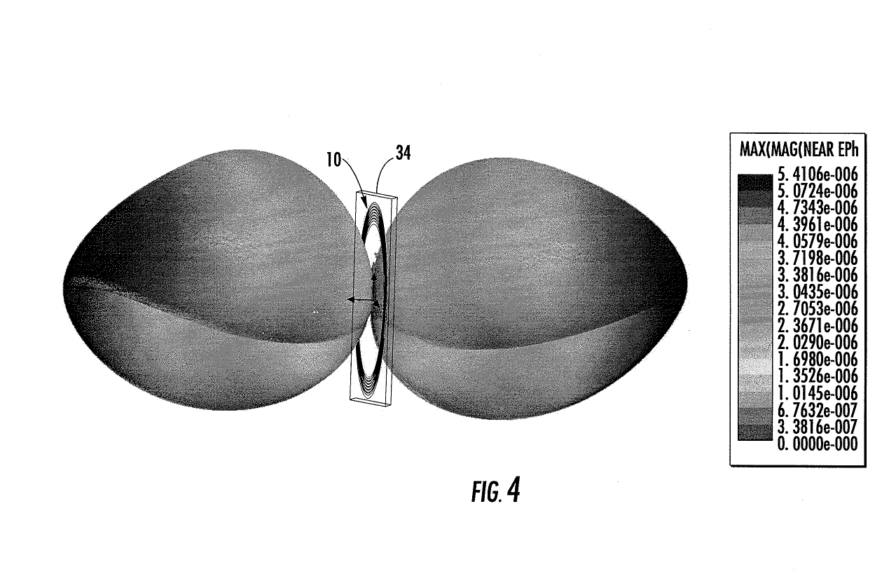

In example embodiments, the impedance behavior of the MRA 10 is distinct from the impedance behavior of a loop from an “equivalent circuit model”. As is well known in the art, conventional loop antennas have very low radiating resistance and impedance, which require an external impedance matching circuit at each resonance to match the 50Ω input impedance. By slowing the wave velocity in the MRA design disclosed herein, a new mode associated in the K-ω curve is generated to achieve improved transmittance an amplitude increase. Referring specifically to FIG. 3, an example of a wave velocity slowing approach is shown. As shown, in order to realize a small antenna size, a miniaturization approach to design is applied. This approach allows an increase in the MRA 10 electrical size, radiation, bandwidth and efficiency as compared to un-miniaturized antennas.

The MRA 10 shown and described herein has several advantageous aspects. First, emulation of effective impedance is between near-zero and 1 when special transmission-line (TL) parameters are chosen. Second, a miniature antenna size using a simple TL approach and slow wave propagation behavior of magnetic waves in the MM Lens is capable. Third, the MRA 10 may be encoded to operate for a single resonant signal. In example embodiments, an MRA 10 is provided to operate at a resonance close to the resonant frequency produced by special parameters of the effective TL inductance and capacitance. Under this condition, the effective impedance near resonant (ε and μ) can be used to match 50Ω transmission-line input, therefore requiring no external matching network.

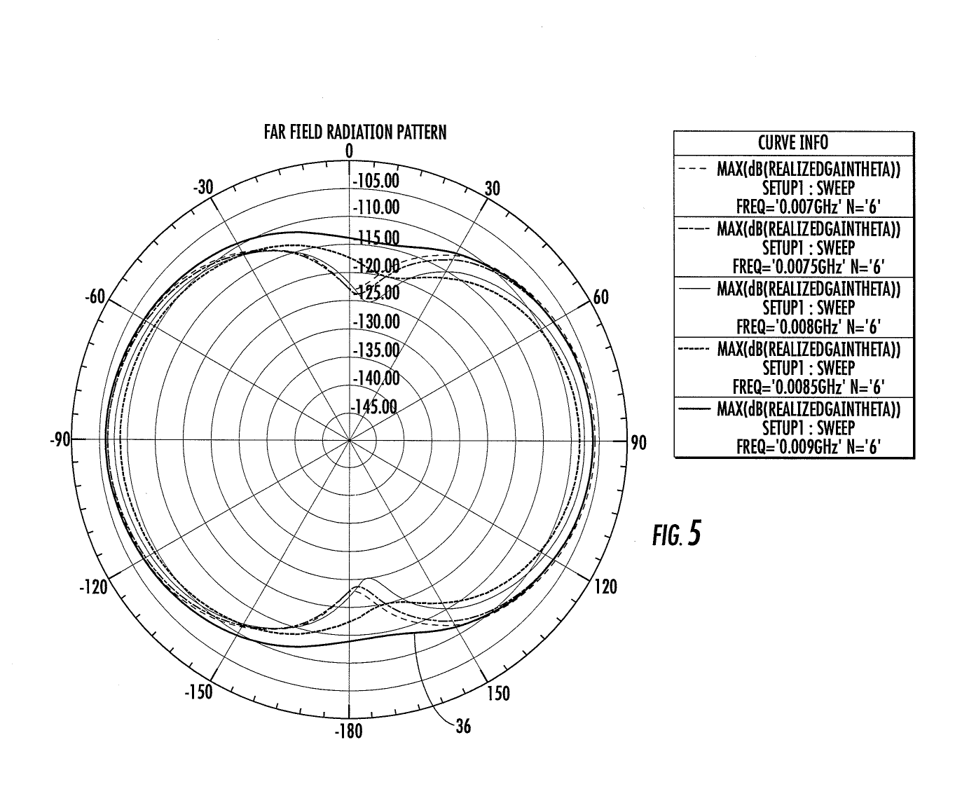

In example embodiments and as best shown in FIGS. 4 and 14, the MRA 10 is connected to a MM Lens structure 34, which, in turn, is incorporated into a MR imaging system 150. In example embodiments, the MM Lens structure 34 may be a 3-layer or 6-layer metalens with a magnetic permeability (μ) of −1. In other example embodiments, the MM Lens structure 34 may be a 3-layer or 6-layer n=−1 metalens. In still other example embodiments, the MM Lens structure 34 may be an isotropic metalens which includes a periodic array of subwavelength cubic unit cells, each unit cell including a conducting loop and capacitor on each of six inner faces. In some example embodiments, the capacitors on loops disposed on opposing sides of a cubic unit cell are disposed on alternate sides of their respective loops. Advantageously, by using the MM Lens in structure 34 with the MRA 10, a small (12-inch) diameter, thin (5 mm thick) non-superconducting resonant MRA at 8.5 MHz (λ=35 m) can be constructed. Such an MRA 10 will not vary performance with use of other nearby or broadcasting antennas, or when in direct contact with water-loaded media.

Referring now to FIG. 4, a predicted near field E field and H field at 8.5 MHz diagram for the MRA 10 of FIG. 1 is illustrated. The characteristics illustrated in FIG. 4 are the result of one variation of an outcome based on the design configuration of FIG. 1 and the miniaturization approach variations shown in FIG. 3.

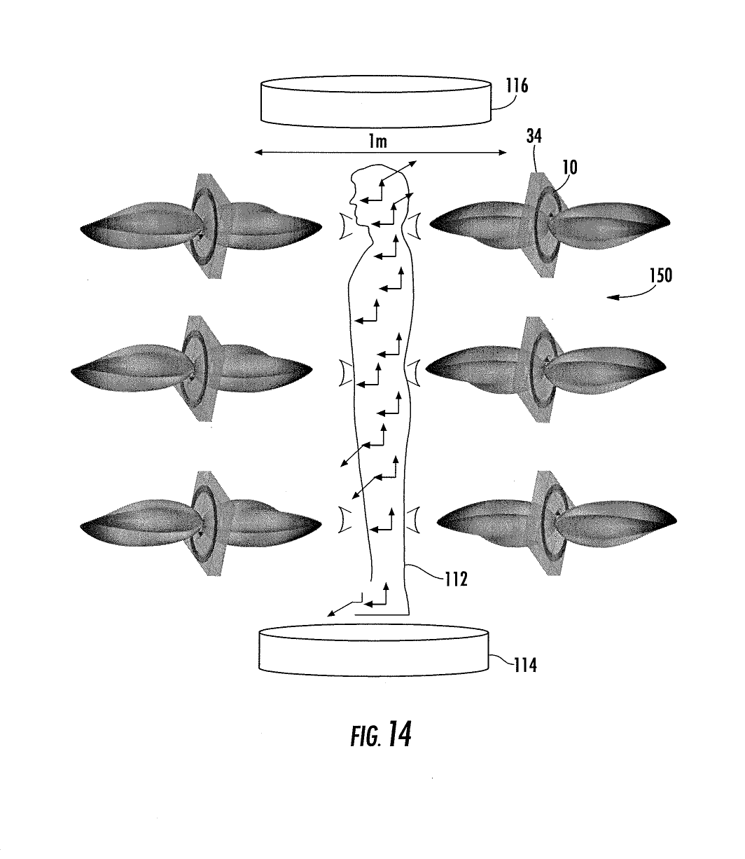

Referring now to FIG. 13, an example direct magnetic imaging (DMI) and detection arrangement 100 is illustrated. As shown, a DMI device 100 is provided with a bore 110 for receiving and maintaining a target or proband 112 during operation. In the example embodiment shown, the target 112 is a human body and is disposed within the bore 110 between two pre-polarization fields 114, 116. However, those skilled in the art will appreciate that the target 112 may be any living organism, or may include machines, devices, structures, archeological findings, rocks, and/or other types or combinations of organic, inorganics, animate, and/or inanimate objects. A detection result of the imaging device 100 is then detected by a detector (not shown) which may be part of the DMI, or in some cases separate. In the example embodiment, when imaging, a low magnetic field source 118 generates a RF pulse 120 that is aimed at the target 112, preferably at 90 degrees perpendicular to the polarizing main field 116, 114 of the imaging device 100. In some example embodiments, the magnetic field detector may be arranged downstream from the magnetic imaging device 100. Such variations of a detector may include a solenoid, a superconducting quantum interference device (SQUID), or a solid state magnetometer. After generating the magnetic field, a focusing step occurs via the MM Lens 122. In the embodiment shown, the MM Lens 122 is 0.5 m thick.

Referring back to FIG. 13, the low magnetic field source is used to excite protons in the target 112. The low magnetic field source allows for imaging in the presence of metals and is generally safer than a high magnetic field source. The MM Lens 122 may collect and focus the magnetic field onto the target 112 (and/or, in some variations onto a detector). The MM Lens 122 focusing may enhance the resolution and may also provide directionality and reduce the need for strong materials and extensive shielding. Tunable MM Lens variations, coupled with variations of multi-frequency sensor arrays, may enable imaging and spectroscopy of different materials types, such as, for example, plastics, metals, organics, etc. Such techniques may also be used in conjunction with superparamagnetic iron oxide nanoparticles (SPIONs) for diagnostic and treatment purposes. An uncooled magneto-electric sensor/cantilever, such as one having SQUID-like performance and/or low power/packing requirements can detect sub-micron Tesla magnetic fields, allowing for fast parallel imaging. By using the MRA 10 (FIG. 14) of the example embodiments, improved transmission and a deeper penetration depth can be achieved.

Referring now to FIG. 14, a variation of the DMI 150 of FIG. 13 equipped with an MRA 10 of FIG. 1 and an MM Lens 34 is shown. As shown, the system 150 is depicted with a transmit (Tx)/receive (Rx) DMI 8.5 MHz MRA system with E-Field (μV/Meter); H-Field (μA/Meter)=E/377. In the example shown, each 8.5 MHz MRA 10 is coupled to a MM Lens 34. In some example embodiments, the MM Lens 34 coupling may only on the Tx or Rx sides, or may be omitted altogether. As shown, the DMI device 150 is provided with a bore 110 (approximately 1 m in width) for receiving and maintaining a target or proband 112 during operation. In the example embodiment shown, the target 112 is a human body and is disposed within the bore 110 between two pre-polarization fields 114, 116.

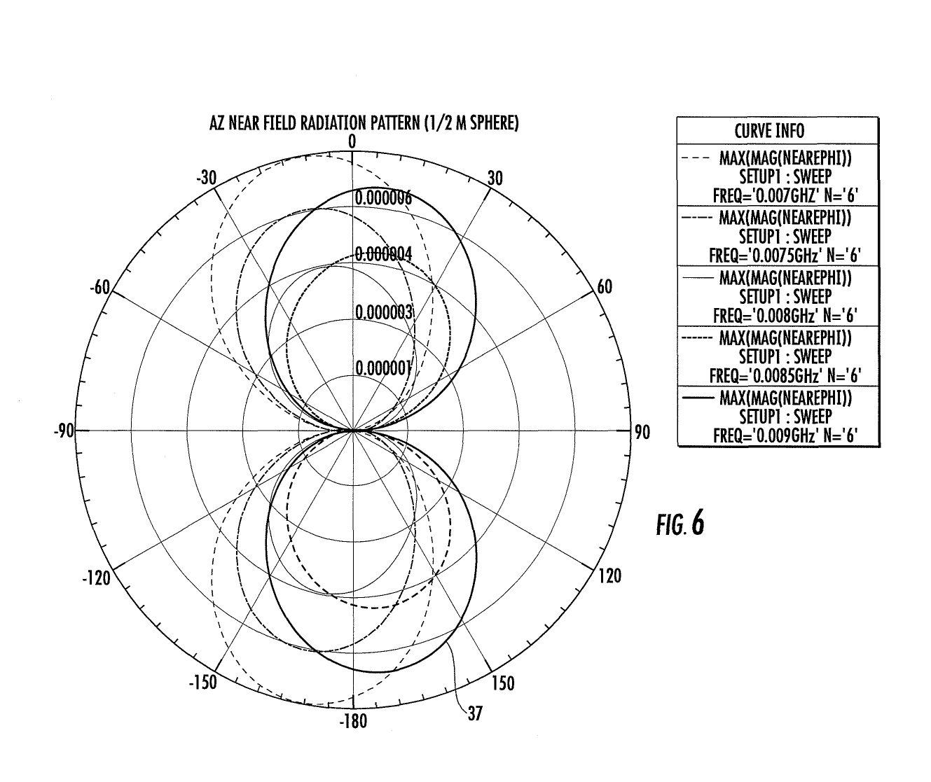

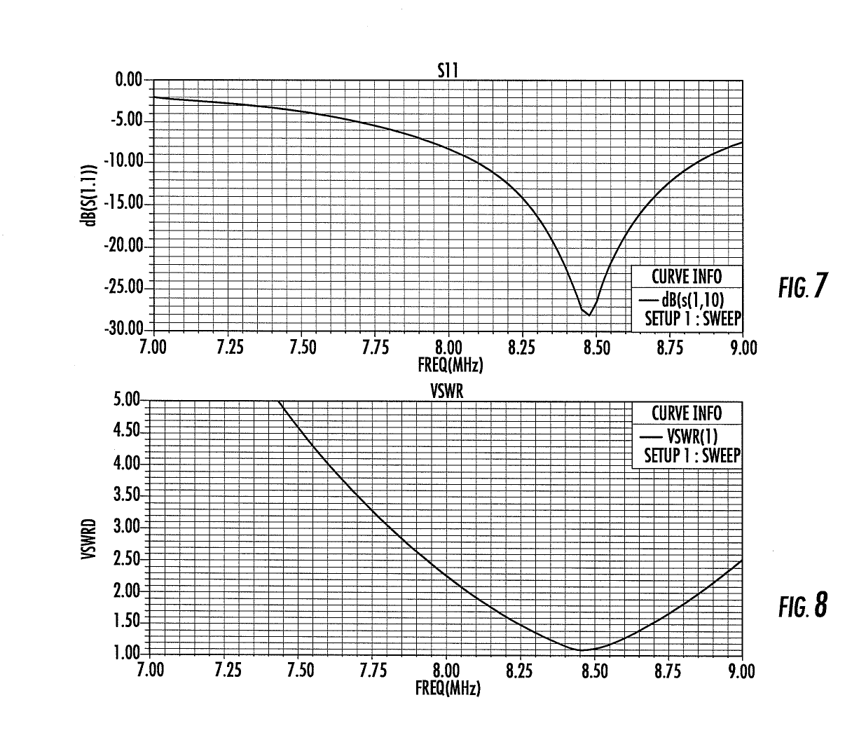

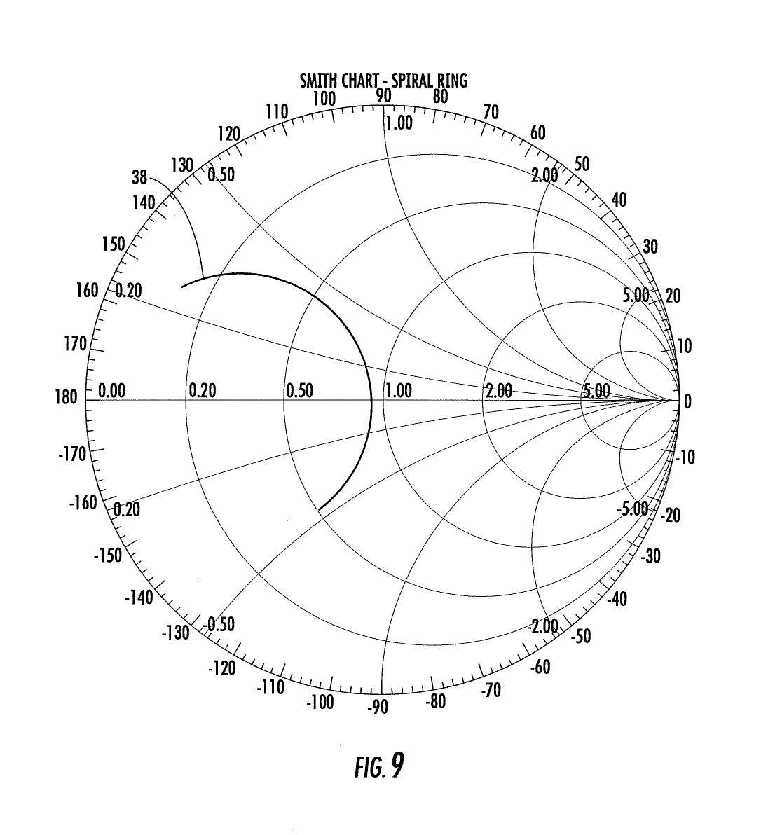

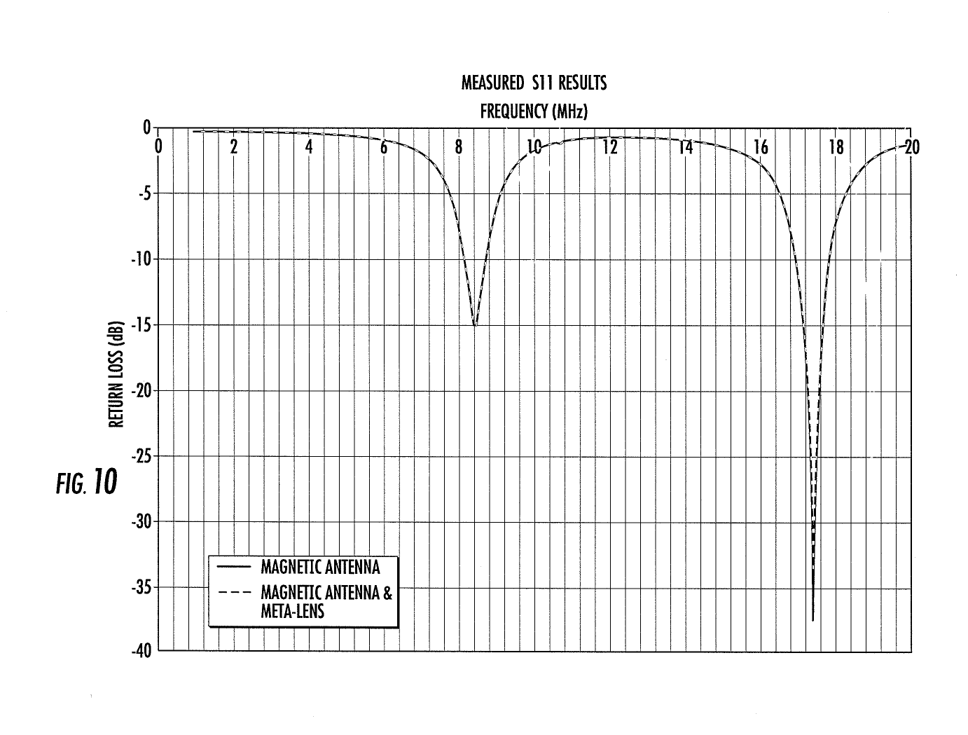

Referring now to FIGS. 5-9, variations of potential performance profiles of variations of MRAs for frequencies between 7 MHz and 9 MHz are shown in both he far and bear fields. More specifically, referring now to FIGS. 5 and 6, predicted far field and near field radiation patterns, 36 and 37, respectively, for the MRA 10 of FIG. 1 are shown for frequencies between 7 MHz and 9 MHz. Referring now to FIG. 7, predicted S₁₁ values for a 50Ω source obtained for the MRA 10 of FIG. 1 is shown. Referring now to FIG. 8, a predicted voltage standing wave ratio (VSWR) values for a 50Ω source obtained for the MRA 10 of FIG. 1 is shown. FIG. 9 shows a response 38 of the MRA 10 of FIG. 1 plotted on a Smith Chart. As will be appreciated by those skilled in the art, a Smith Chart is plotted on the complex reflection coefficient plane in two dimensions and is scaled in normalized impedance, normalized admittance or bot. A commonly used normalization impedance is 50Ω. The Smith Chart is circumferentially scaled in wavelengths and degrees.

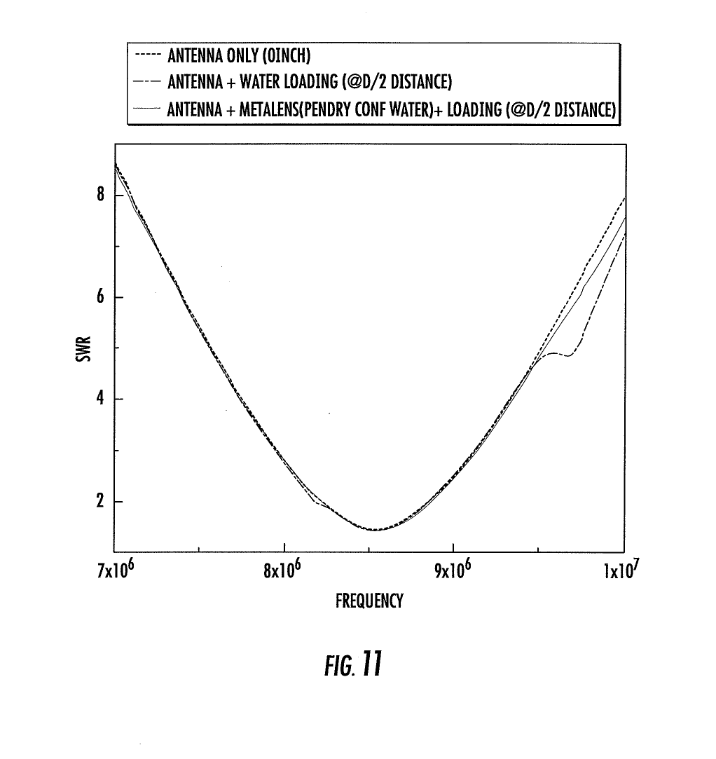

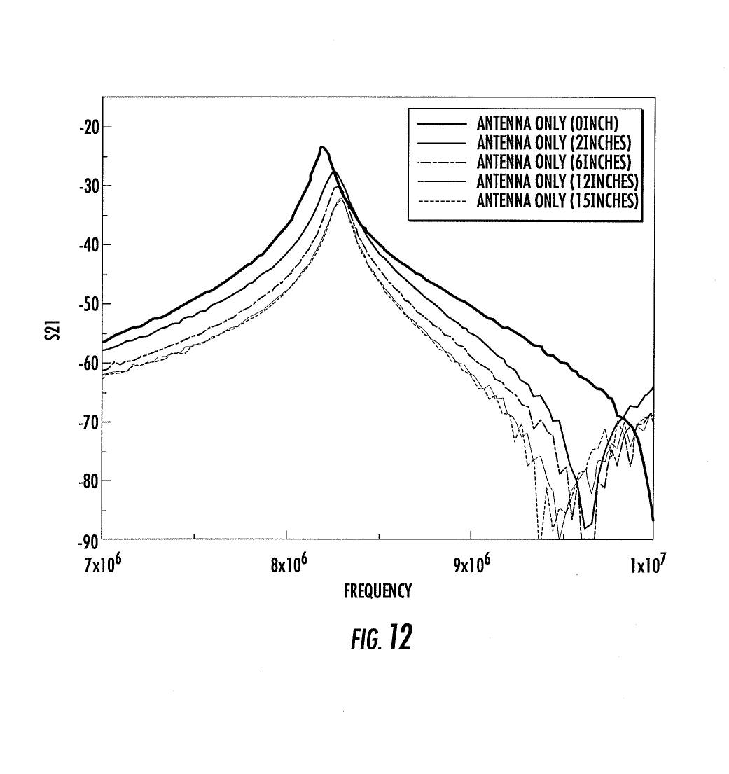

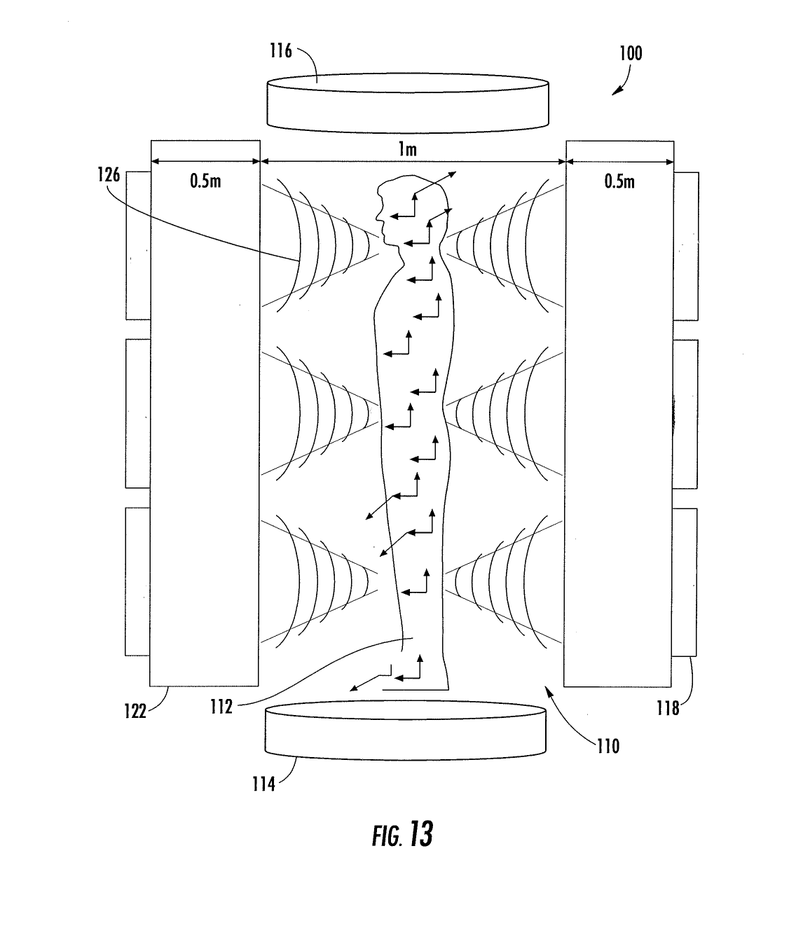

Referring now to FIGS. 10-12, comparative, measured performance of the variations of MRAs 10 as disclosed herein are shown, both with and without a connection to the MM Lens 34. More specifically and referring to FIG. 10, measured S₁₁ values for a 50Ω source obtained for the MRA of FIG. 1 in comparison to the MRA connected to a MM Lens structure are shown. FIG. 11 illustrates comparative, measured SWR results for the MRA 10 of FIG. 1, the MRA 10 of FIG. 1 in conjunction with water loading and the MRA 10 of FIG. 1 in conjunction with a MM Lens 34 and water loading. Further, FIG. 12 illustrates comparative, measured S₂₁ results for various distances across various frequencies.

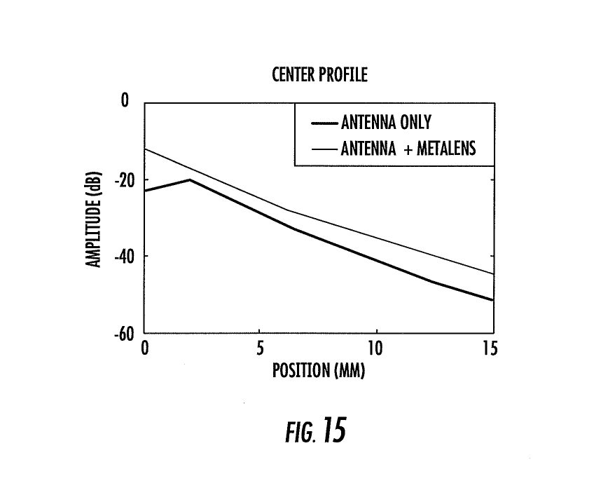

As can be seen from the above referenced graphs and diagrams, the disclosed MRA 10 yields optimal return loss properties at 8.5 MHz. Further, the MRA 10 tested was matched to 50Ω without a need for a matching network and little or no loading effect was observed on the MRA 10 in testing with water and with a MM Lens 34. Still further, no loading on Rx was observed after 12 inches from Tx. Finally, the MRA/MM Lens configuration shows improved performance as compared to the performance of the MM Lens alone, as can be seen in the field decay plot of FIG. 15 (which depicts the field decay for the MRA 10 and the MRA 10 in conjunction with the MM Lens 34).

The embodiments described above provide advantages over conventional devices and associated systems and methods. It will be apparent to those skilled in the art that various modifications and variations can be made to the embodiments without departing from the spirit and scope of the claims. Thus, it is intended that the embodiments cover the modifications and variations of this description provided they come within the scope of the appended claims and their equivalents. Furthermore, the foregoing description and best mode for practicing the embodiments are provided for the purpose of illustration only and not for the purpose of limitation—the embodiments being defined by the claims.

What is claimed is:

1. A resonant magnetic ring antenna, comprising:
a dielectric substrate having opposing first and second sides;
a first ring element disposed upon the first side of the substrate, the first ring element comprising a trace having a spiral configuration with an outer radius, an inner radius, a spacing, and a number of turns;
a second ring element disposed upon the second side of the substrate, the second ring element comprising a trace having a spiral configuration with an outer radius, an inner radius, a spacing, and a number of turns; and
wherein the resonant magnetic ring antenna is configured to concentrate radio frequency (RF) electromagnetic fields over a controlled volume at a specified distance from an imaging device in which it is incorporated.

2. The resonant magnetic ring antenna of claim 1, wherein the resonant magnetic ring antenna is overlayed upon a matematerial (MM) Lens.

3. The resonant magnetic ring antenna of claim 2, wherein the MM Lens is isotropic.

4. The resonant magnetic ring antenna of claim 2, wherein the MM lens includes a periodic array of subwavelength cubic unit cells, each cubic unit cell including a conducting loop and capacitor on each of six inner faces.

5. The resonant magnetic ring antenna of claim 4, wherein the capacitors on loops disposed on opposing sides of a cubic unit cell are disposed on alternate sides of their respective loops.

6. The resonant magnetic ring antenna of claim 2, wherein the MM lens has a magnetic permeability (μ) of −1.

7. The resonant magnetic ring antenna of claim 1, wherein the resonant magnetic ring antenna has a robust 50Ω (ohm) matched concentrated field.

8. The resonant magnetic ring antenna of claim 1, wherein the magnetic resonant ring antenna remains matched upon loading into an imaging device without the need for tuning capacitors to compensate for loading effects.

9. The resonant magnetic ring antenna of claim 1, wherein the substrate is a ceramic-filled polytetrofluroethylene (PTFE) material.

10. The resonant magnetic ring antenna of claim 1, wherein the spiral configuration may have any circular shape, elliptical shape, or polygonal shape.

11. The resonant magnetic ring antenna of claim 1, wherein the number of turns is six (6) and the spacing is approximately 0.06 inches.

12. The resonant magnetic ring antenna of claim 1, wherein the outer radius is 5.75 inches and the inner radius is 4.75 inches.

13. The resonant magnetic ring antenna of claim 1, wherein the substrate includes an aperture which substantially aligns with the inner radius of the first and second ring elements and which is substantially the same size as the inner radius of the first and second ring elements.

14. A resonant magnetic ring antenna arrangement, comprising:
a resonant magnetic ring antenna, comprising a dielectric substrate having opposing first and second sides; a first ring element disposed upon the first side of the substrate, the first ring element comprising a trace having a spiral configuration with an outer radius, an inner radius, a spacing, and a number of turns; and a second ring element disposed upon the second side of the substrate, the second ring element comprising a trace having a spiral configuration with an outer radius, an inner radius, a spacing, and a number of turns; and
wherein the resonant magnetic ring antenna is overlayed upon and connected to a matematerial (MM) Lens;
wherein the resonant magnetic ring antenna is configured to concentrate radio frequency (RF) electromagnetic fields over a controlled volume at a specified distance from an imaging device in which it is incorporated.

15. The resonant magnetic ring antenna arrangement of claim 14, wherein the resonant magnetic ring antenna has a robust 50Ω (ohm) matched concentrated field.

16. The resonant magnetic ring antenna arrangement of claim 14, wherein the magnetic resonant ring antenna remains matched upon loading into the imaging device without the need for tuning capacitors to compensate for loading effects.

17. The resonant magnetic ring antenna arrangement of claim 14, wherein the MM lens has a magnetic permeability (μ) of −1.

18. The resonant magnetic ring antenna arrangement of claim 14, wherein concentrated radio frequency (RF) electromagnetic fields are on the order of 0.2 Tesla to 17 Tesla.

19. An imaging device, comprising:
a magnetic field generating device that generates a magnetic field for imaging;
a magnetic field detector that detects a magnetic field associated with an imaging target, the associated magnetic field being caused by an interaction of the generated magnetic field and the imaging target; and
a focusing device that focuses the magnetic field before it is detected by the magnetic field detector, the focusing device including a magnetic metamaterial lens coupled to a resonant magnetic ring antenna, the resonant magnetic ring antenna comprising a generally planar substrate having opposing first and second sides, first and second ring elements disposed upon the opposing first and second sides of the substrate in a corresponding location, wherein the first and second ring elements each comprising a trace having a spiral configuration with an outer radius, an inner radius, a spacing, and a number of turns.

20. The imaging device of claim 19, wherein the resonant magnetic ring antenna is configured to concentrate radio frequency (RF) electromagnetic fields over a controlled volume at a specified distance from the imaging device.
